(19) United States
(12) Patent Application Publication
(10) Pub. No.: US 2020/0035614 A1
(43) Pub. Date: Jan. 30, 2020

(54) PACKAGE STRUCTURE AND MANUFACTURING METHOD THEREOF

(71) Applicant: Powertech Technology Inc., Hsinchu County (TW)

(72) Inventors: Nan-Chun Lin, Hsinchu County (TW); Hung-Hsin Hsu, Hsinchu County (TW)

(73) Assignee: Powertech Technology Inc., Hsinchu County (TW)

(21) Appl. No.: 16/048,351

(22) Filed: Jul. 30, 2018

(51) Int. Cl. H01L 23/552; H01L 23/13; H01L 23/31; H01L 23/00; H01L 21/56; H01L 23/367; H01L 21/683

(52) U.S. Cl. CPC H01L 23/552; H01L 2224/73253; H01L 23/3128; H01L 24/20; H01L 21/565; H01L 24/19; H01L 24/83; H01L 21/568; H01L 23/3675; H01L 21/6835; H01L 24/73; H01L 2224/32245; H01L 2224/83005; H01L 2924/3025; H01L 2224/0231; H01L 2224/02379; H01L 2224/13024; H01L 24/13; H01L 21/561; H01L 24/97; H01L 2221/68363; H01L 2224/73267; H01L 23/13

(57) ABSTRACT

A package structure including a frame structure, a die, an encapsulant, and a redistribution structure is provided. The frame structure has a cavity. The die is disposed in the cavity. The die has an active surface, a rear surface opposite to the active surface, a plurality of lateral sides connecting the active surface and the rear surface, and a plurality of connection pads disposed on the active surface. The encapsulant encapsulates at least a portion of the frame structure and lateral sides of the die. The redistribution structure is disposed on the encapsulant and the active surface of the die. The connection pads are directly in contact with the redistribution structure.

### BACKGROUND OF THE INVENTION

### Field of the Invention

The disclosure generally relates to a package structure and a manufacturing method thereof, and in particular, to a package structure having a frame structure and a manufacturing method thereof.

### Description of Related Art

Development of semiconductor package technology in recent years has focused on delivering products with smaller volume, lighter weight, higher integration level, and lower manufacturing cost. Continuing to miniaturize the package structure while keeping the cost of manufacturing low and the performance of the packaged semiconductor die high has become a challenge to researchers in the field.

### SUMMARY OF THE INVENTION

The disclosure provides a package structure and a manufacturing method thereof, which effectively enhances the reliability of the package structure at lower manufacturing cost.

The disclosure provides a package structure including a frame structure, a die, an encapsulant, and a redistribution structure. The frame structure has a cavity. The die is disposed in the cavity. The die has an active surface, a rear surface opposite to the active surface, a plurality of lateral sides connecting the active surface and the rear surface, and a plurality of connection pads disposed on the active surface. The encapsulant encapsulates at least a portion of the frame structure and the lateral sides of the die. The redistribution structure is disposed on the encapsulant and the active surface of the die. The connection pads are in physical contact with the redistribution structure.

The disclosure provides a manufacturing method of a package structure. The method includes at least the following steps. A frame structure having a cavity is provided. A die is placed in the cavity of the frame structure. The die has an active surface, a rear surface opposite to the active surface, a plurality of lateral sides connecting the active surface and the rear surface, and a plurality of connection pads disposed on the active surface. A mold chase having a sealing film formed thereon is placed over the frame structure and the die. An encapsulant is formed to encapsulate at least a portion of the frame structure and the lateral sides of the die. A redistribution structure is formed over the encapsulant and the die. The connection pads are in physical contact with the redistribution structure.

Based on the above, the frame structure within the package structure may serve as a carrier during the manufacturing process of the package structure. Thus, the use of a temporary carrier may be eliminated. In other words, the costly transfer bonding process performed in the conventional manufacturing process of the package structure may be removed to reduce the cost of fabrication. Moreover, since the frame structure may be formed by rigid materials, the frame structure is able to provide rigidity and strength to the package structure. As such, the problems of panel warpage and package chipping/breaking/cracking may be sufficiently prevented, thereby increasing the yield and the reliability of the package structure. Furthermore, the frame structure may also serve the function of heat dissipation and electromagnetic interference (EMI) shielding. As a result, the performance of the package structure may be further enhanced.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles presented in the disclosure. Identical or similar numbers refer to identical or similar elements throughout the drawings.

FIG. 1A to FIG. 1G are schematic cross-sectional views illustrating a manufacturing method of a package structure according to some embodiments of the disclosure.

FIG. 2 is a schematic top view illustrating the frame structure and the die in FIG. 1B.

FIG. 3A to FIG. 3G are schematic cross-sectional views illustrating a manufacturing method of a package structure according to some alternative embodiments of the disclosure.

FIG. 4 is a schematic side view illustrating an intermediate stage of the manufacturing method shown in FIG. 3C.

FIG. 5A to FIG. 5C are cross-sectional views illustrating some steps of a manufacturing method of a package structure according to some embodiments of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

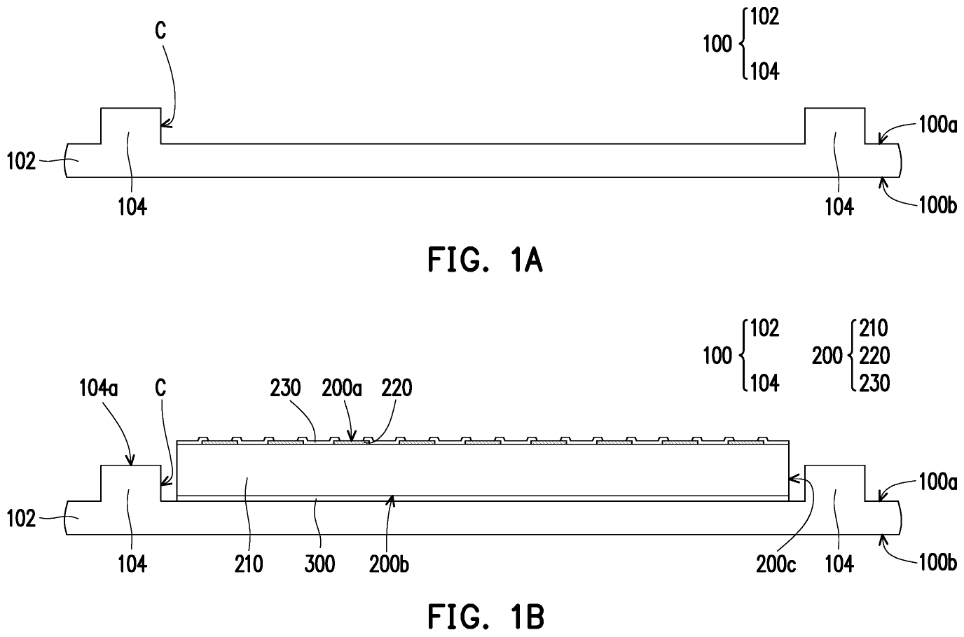

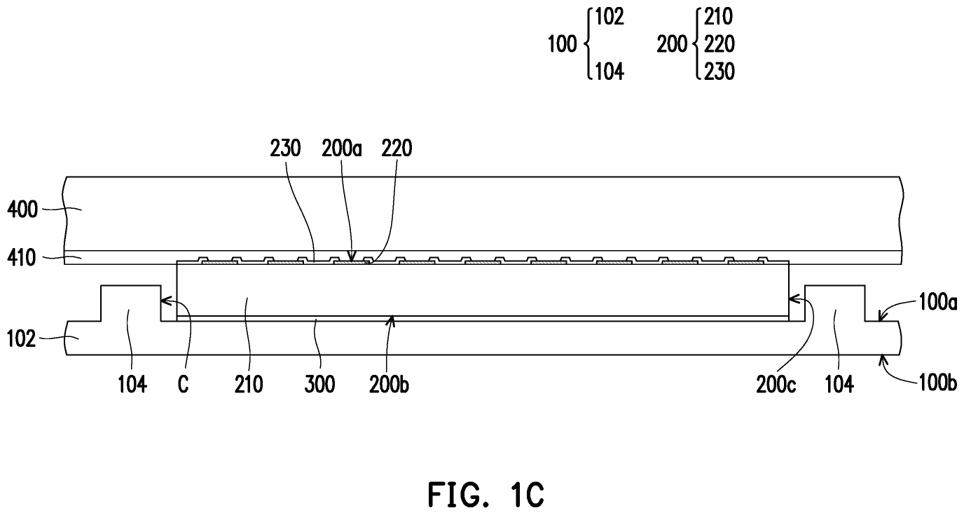

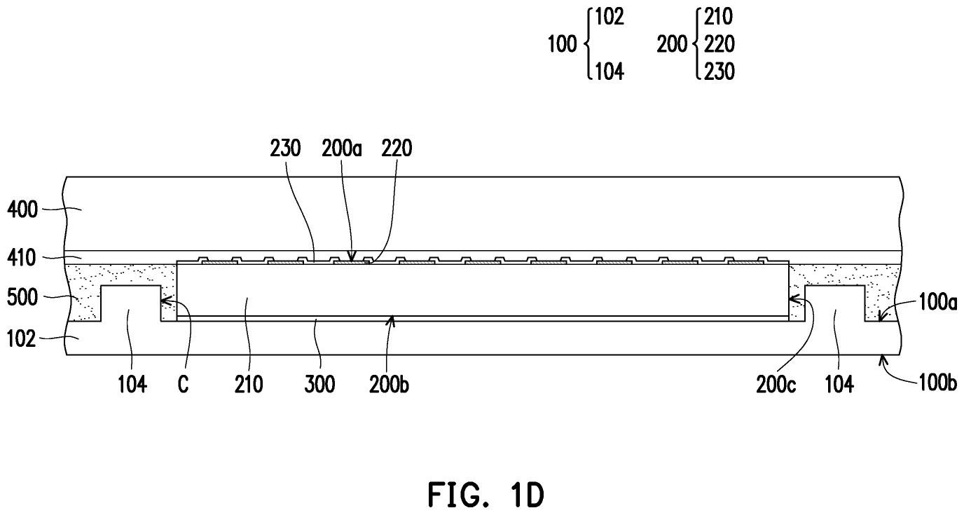

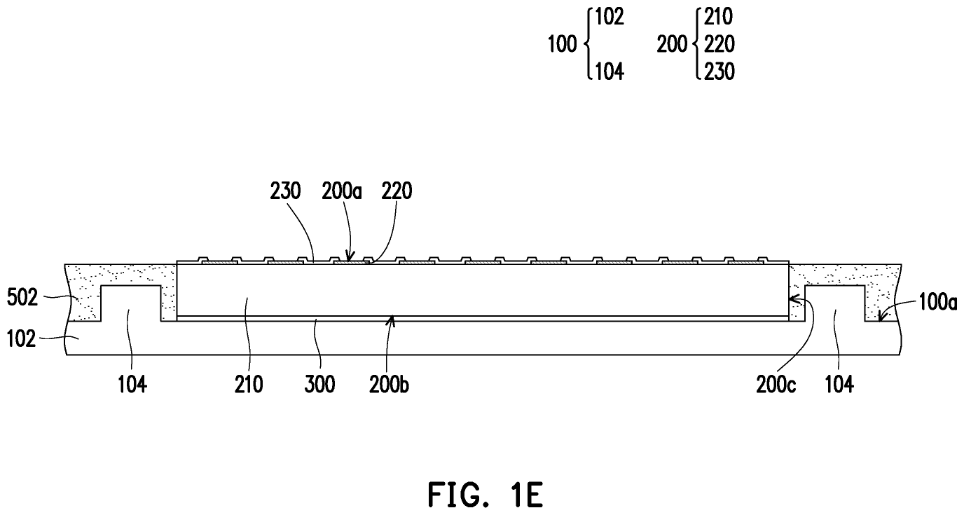

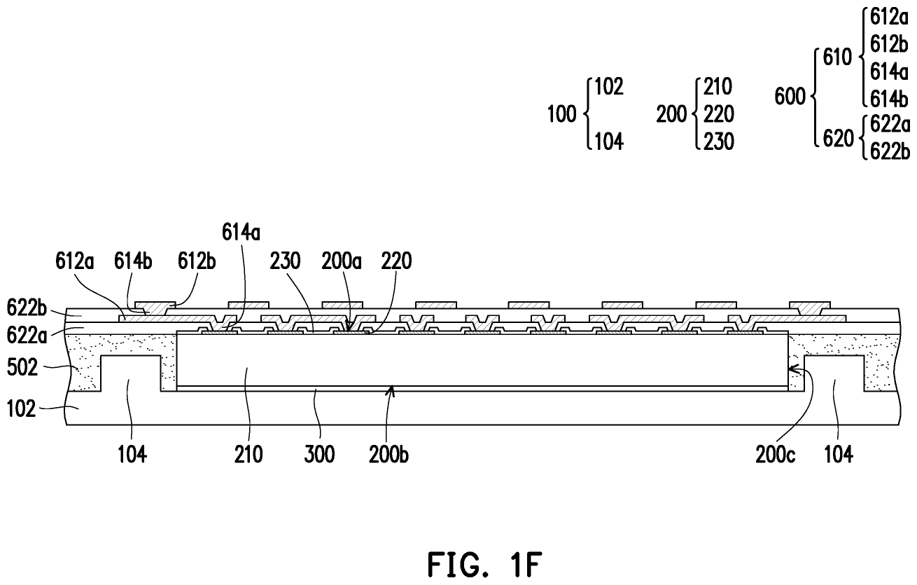

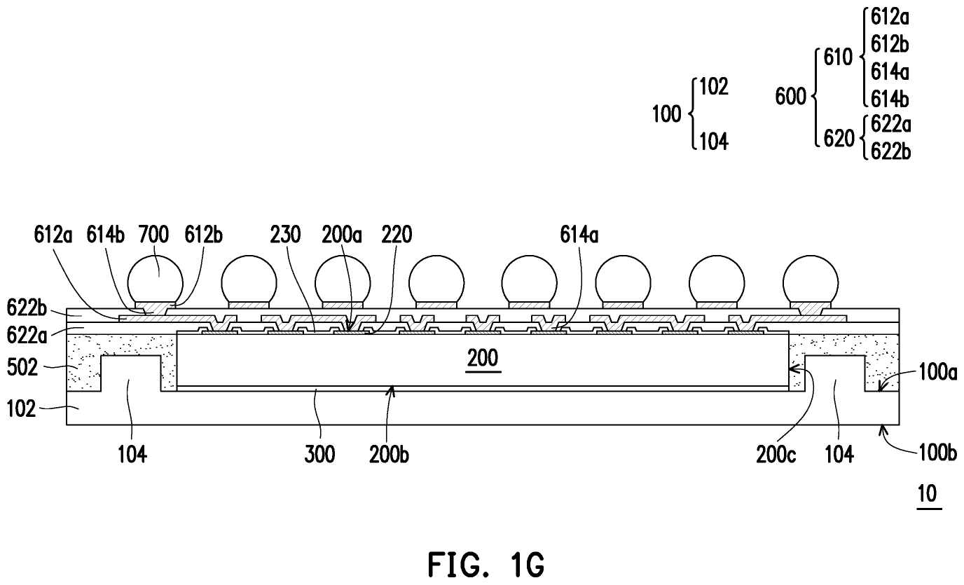

FIG. 1A to FIG. 1G are schematic cross-sectional views illustrating a manufacturing method of a package structure 10 according to some embodiments of the disclosure. Referring to FIG. 1A, a frame structure 100 is provided. The frame structure 100 has a first surface 100a and a second surface 100b opposite to the first surface 100a. The frame structure 100 includes a body 102 and a plurality of protrusions 104 protruding from the body 102. For example, the protrusions 104 may protrude from the first surface 100a of the frame structure 100. In some embodiments, the body 102 and the protrusions 104 are configured to form a cavity C. For example, each of the protrusions 104 may form a closed loop as seen from a top view, thereby defining the cavity C enclosed by the protrusion 104. In other words, the frame structure 100 has a plurality of cavities C defined by the corresponding protrusion 104. In some embodiments, the protrusions 104 and the cavities C may be arranged in an array. For simplicity, only one set of the protrusion 104 and the cavity C is illustrated in FIG. 1A. In some embodiments, portions of the first surface 100a of the frame structure 100 may also be referred to, in some embodiments, as a bottom surface of the cavity C. In some embodiments, the frame structure 100 may be formed from a conductive substrate to provide isolation and protection against electromagnetic interference (EMI) and may have a high strength and stiffness to provide structural support. In addition, the frame structure 100 may be made of a material having low thermal capacity and high thermal dissipation, such that the frame structure 100 may act as a heatsink to dissipate heat generated from the subsequently formed components. For example, the material of the frame structure 100 may include copper, metallic alloy, steel, other suitable materials, or a combination thereof.

Referring to FIG. 1B, a die 200 is placed in the cavity C of the frame structure 100. In some embodiments, the die 200 may be an ASIC (Application-Specific Integrated Circuit). However, the disclosure is not limited thereto, and other suitable devices may be adapted as the die 200. The die 200 includes a semiconductor substrate 210, a plurality of connection pads 220, and a passivation layer 230. The die 200 has an active surface 200a, a rear surface 200b opposite to the active surface 200a, and a plurality of lateral sides 200c connecting the active surface 200a and the rear surface 200b. The connection pads 220 are disposed on the active surface 200a. In some embodiments, the semiconductor substrate 210 may be a silicon substrate having active components and, optionally, passive components formed therein. Examples of the active components include transistors or the like. Examples of the passive components include resistors, capacitors, inductors, or the like. The connection pads 220 are distributed over the semiconductor substrate 210 of the die 200. In some embodiments, the connection pads 220 may include aluminum pads, copper pads, or other suitable metal pads. The passivation layer 230 is formed over the semiconductor substrate 210 to cover a portion of each connection pad 220. The passivation layer 230 has a plurality of contact openings revealing another portion of each connection pad 220 for electrical connection. The passivation layer 230 may be made of polymeric materials. In some embodiments, the passivation layer 230 may be a silicon oxide layer, a silicon nitride layer, a silicon oxy-nitride layer, or a dielectric layer formed by other suitable dielectric materials.

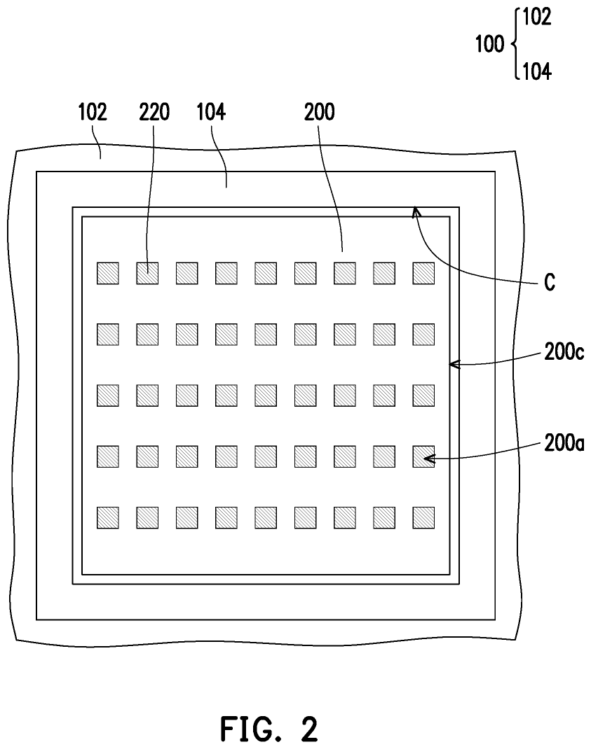

The die 200 may be placed in the cavity C of the frame structure 100 using the following steps. An adhesive layer 300 may be formed on the rear surface 200b of the die 200. The adhesive layer 300 is forming to provide low die shift and good thermal dissipation. For example, the adhesive layer 300 may include a die attach film (DAF), a thermal interface material (TIM), an epoxy, or other suitable adhesive materials. Thereafter, the die 200 having the adhesive layer 300 formed thereon is placed in the cavity C of the frame structure 100 such that the rear surface 200b of the die 200 is attached to the frame structure 100 through the adhesive layer 300. For example, the adhesive layer 300 may be disposed between the rear surface 200b of the die 200 and the body 102 of the frame structure 100. The die 200 is disposed such that the active surface 200a of the die 200 faces upward and away from the frame structure 100. In some embodiments, the adhesive layer 300 is in physical contact with the bottom surface of the cavity C. It should be noted that the foregoing sequence merely serves as an illustrative example, and the disclosure is not limited thereto. In some alternative embodiments, the adhesive layer 300 may be formed in the cavity C of the frame structure 100 prior to the attachment of the die 200. The relative configuration of the die 200 and the frame structure 100 will be described below in conjunction with FIG. 2. FIG. 2 is a schematic top view illustrating the frame structure 100 and the die 200 in FIG. 1B. Referring to FIG. 1B and FIG. 2, the protrusion 104 of the frame structure 100 forms a rectangular closed loop surrounding the die 200. In some embodiments, the cavity C is larger than the die 200. For example, the cavity C is able to accommodate the die 200 such that the lateral sides 200c of the die 200 are spaced apart from the protrusion 104. In some embodiments, the die 200 is placed such that the active surface 200a of the die 200 is located at a level height higher than that of a surface 104a of the protrusion. Although the protrusion 104 is illustrated as a rectangular closed loop, the shape thereof is not limited thereto. In some alternative embodiments, the protrusion 104 may take the form of a circular closed loop, a polygonal closed loop, or any other closed loop as long as the protrusion 104 surrounds the periphery of the die 200.

Referring to FIG. 1C, a mold chase 400 having a sealing film 410 formed thereon is placed over the die 200. The sealing film 410 and the mold chase 400 may be disposed on the active surface 200a of the die 200. The sealing film 410 may be pressed against the active surface 200a such that the connection pads 220 of the die 200 are completely embedded in the sealing film 410. As mentioned above, the active surface 200a of the die 200 is located at a level height higher than the surface 104a of the protrusion 104. In this way, the mold chase 140 and the sealing film 410 are placed over the die 200 in an elevated manner. In other words, the protrusion 104 of the frame structure 100 is separate from the sealing film 410. In some embodiments, a material of the sealing film 410 includes thermostable epoxy resin or any suitable material having high thermal resistance. The sealing film 410 may encompass elasticity. The sealing film 410 may be easily peeled off from the active surface 200a of the die 200 and the subsequently formed encapsulation material without leaving residues and without damaging these elements. In some embodiments, the sealing film 410 may serve as a protective layer to protect the mold chase 140 from being damaged during subsequent processes. For example, a Young's modulus of the sealing film 410 may be less than 1 GPa. In some embodiments, the mold chase 400 may be made of metallic materials having strong heat resistance. In other words, the mold chase 400 may be made of materials able to withstand high temperature for the subsequent molding process. For example, the material of the mold chase 400 may include steel or the like.

Referring to FIG. 1D, an encapsulation material 500 is filled into a gap between the sealing film 410, the frame structure 100, and the die 200. The encapsulation material 500 may be a molding compound. For example, the encapsulation material 500 may include insulating materials such as polymers, epoxy, or other suitable resins. The encapsulation material 500 may be in solid form at room temperature. In some embodiments, the encapsulation material 500 is first melted. Subsequently, the encapsulation material 500 is transferred or forced into the gap between the sealing film 410, the frame structure 100, and the die 200. In some embodiments, the encapsulation material 500 is forced into the gap along a direction parallel to the rear surface 200b of the die 200. The encapsulation material 500 may be transferred into the gap from a horizontal direction. In some embodiments, the foregoing process may be referred to as a transfer molding process. During the transfer molding process, a clamp force may be applied onto the mold chase 400 such that sealing film 410 is firmly pressed against the active surface 200a of the die 200. As mentioned above, since the connection pads 220 of the die 200 are well protected and sealed by the sealing film 410, the sealing film 410 may block the encapsulation material 500 from damaging the connection pads 220 during the transfer molding process. That is, during the transfer molding process, the sealing film 410 is able to protect the active surface 200a of the die 200 from molding penetration. As such, the electrical connection between the connection pads 220 and the subsequently formed elements may be ensured, thereby enhancing the reliability of the subsequently formed package structure 10. In some embodiments, a Young's modulus of the encapsulation material 500 ranges between 10 GPa and 20 GPa.

Referring to FIG. 1E, the mold chase 400 and the sealing film 410 are removed and the encapsulation material 500 is cured to form an encapsulant 502. In some embodiments, the curing temperature may range between 130° C. and 175° C. The encapsulant 502 is formed over the frame structure 100 and covers the first surface 100a of the frame structure 100. For example, the encapsulant 502 may completely encapsulate the protrusion 104 of the frame structure 100. The encapsulant 502 may further encapsulate the lateral sides 200c of the die 200. Since the encapsulant 502 is formed to fill the gap between the sealing film 410, the frame structure 100, and the die 200 (shown in FIG. 1D), at least a portion of the encapsulant 502 is disposed between the die 200 and the frame structure 100. For example, at least a portion of the encapsulant 502 is disposed between the lateral sides 200c and the protrusion 104. Upon removal of the mold chase 400 and the sealing film 410, the active surface 200a of the die 200 may be exposed.

Referring to FIG. 1F, a redistribution structure 600 is formed over the encapsulant 502 and the active surface 200a of the die 200. The redistribution structure 600 is electrically connected to the connection pads 220 of the die 200. The redistribution structure 600 may include at least one dielectric layer 620 and a plurality of conductive elements 610 embedded in the dielectric layer 620. In some embodiments the dielectric layers 620 may be made of non-organic or organic dielectric materials such as silicon oxide, silicon nitride, silicon carbide, silicon oxynitride, polyimide, benzocyclobutene (BCB), or the like. The dielectric layers 620 may be formed by spin-on coating, chemical vapor deposition (CVD), plasma-enhanced chemical vapor deposition (PECVD), or the like. The conductive elements 610 may be made of copper, aluminum, nickel, gold, silver, tin, a combination thereof, or other suitable conductive materials. The conductive elements 610 may be formed by sputtering, evaporation, electro-less plating, or electroplating.

The redistribution structure 600 may include two dielectric layers 620 (a first dielectric layer 622a and a second dielectric layer 622b). However, the number of the dielectric layer 620 is not limited and may be adjusted based on circuit design. The conductive elements 610 may include a plurality of trace layers (a first trace layer 612a and a second trace layer 612b) and a plurality of interconnect structures (a plurality of first interconnect structures 614a and a plurality of second interconnect structures 614b) electrically connecting the connection pads 220, the first trace layer 612a, and the second trace layer 612b. The first dielectric layer 622a is disposed on the encapsulant 502 and the active surface 200a of the die 200. The first dielectric layer 622a has a plurality of contact openings exposing the connection pads 220 of the die 200. The first interconnection structures 614a are disposed in the contact openings and are in physical contact with both the first trace layer 612a and the connection pads 220, thereby rendering electrical connection between the die 200 and the redistribution structure 600. In other words, the redistribution structure 600 is in physical contact with the connection pads 220 of the die 200. Therefore, certain steps in the conventional die forming process (for example, the formation of conductive bumps over connection pads of the die) may be removed to reduce the process complexity and manufacturing cost of the subsequently formed package structure 10. The second dielectric layer 622b covers the first trace layer 612a. Similar to the first dielectric layer 622a, the second dielectric layer 622b also has a plurality of contact openings exposing part of the first trace layer 612a such that the first trace layer 612a may be electrically connected to other trace layers (for example, the second trace layer 612b) through the second interconnect structures 614b. The second trace layer 612b may be used for electrical connection with elements formed in the subsequent processes. In some embodiments, the second trace layer 612b may be referred to as under-bump metallization (UBM).

The protrusion 104 of the frame structure 100 is separate from the redistribution structure 600. For example, a portion of the encapsulant 502 may be disposed between the protrusion 104 and the redistribution structure 600 to isolate these elements. The encapsulant 502 may serve as a buffer layer between the protrusion 104 and the redistribution structure 600 to further ensure the reliability of the subsequently formed package structure 10.

Referring to FIG. 1G, after forming the redistribution structure 600, a plurality of conductive terminals 700 are formed on the redistribution structure 600 opposite to the encapsulant 502. In some embodiments, the conductive terminals 700 are disposed on the second trace layer 612b. The conductive terminals 700 may be formed by, for example, a ball placement process and a reflow process. In some embodiments, the conductive terminals 700 are conductive bumps such as solder balls. However, the disclosure is not limited thereto. Other possible forms and shapes of the conductive terminals 700 may be utilized according to design requirements. For example, the conductive terminals 700 may take the form of conductive pillars or conductive posts in some alternative embodiments.

After formation of the redistribution structure 600, a singulation process may be performed to obtain a plurality of package structures 10. The singulation process includes, for example, cutting with rotating blades or laser beams. In some embodiments, the singulation process is performed on a portion of the frame structure 100 having a thinner thickness to maximize the saw blade lifetime. For example, the scribe line for sawing may be located on the body 102 of the frame structure 100 to ensure the sawing thickness on the frame structure 100 is minimized. In some embodiments, before the singulation process, a thinning process may be optionally performed to reduce the overall thickness of the body 102 of the frame structure 100. For example, a mechanical grinding process, a chemical mechanical planarization (CMP) process, or other suitable processes may be performed on the second surface 100b of the frame structure 100. The thinning process may be conducted to reduce the overall height of the package structure 10.

The frame structure 100 of the package structure 10 may serve as a carrier during the manufacturing process of the package structure 10. Thus, the use of a temporary carrier may be eliminated. In other words, the costly transfer bonding process performed in the conventional manufacturing process of the package structure may be removed to reduce the cost of fabrication. Moreover, since the frame structure 100 may be formed by rigid materials, the frame structure 100 is able to provide rigidity and strength to the package structure. As such, the problems of panel warpage and package chipping/breaking/cracking may be sufficiently prevented, thereby increasing the yield and the reliability of the package structure 10. Furthermore, since the frame structure 100 may be made of a material having low thermal capacity and high thermal dissipation, the frame structure 100 may also serve the function of heat dissipation. As a result, the performance of the package structure 10 may be further enhanced.

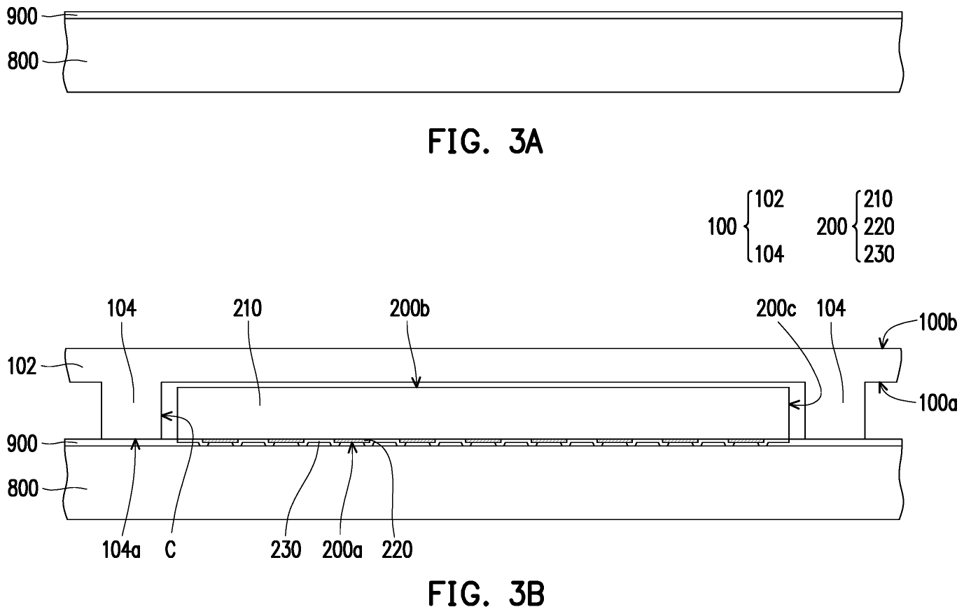

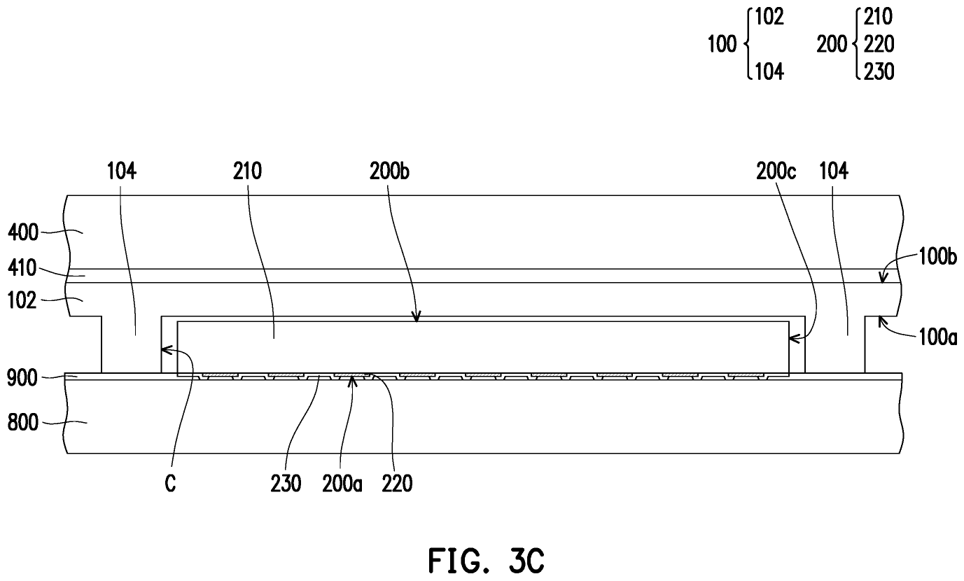

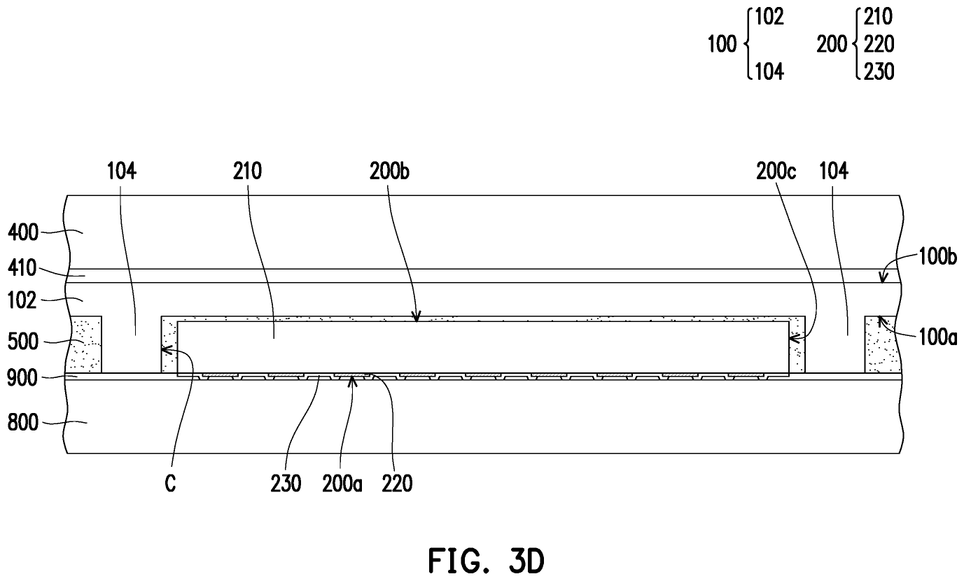

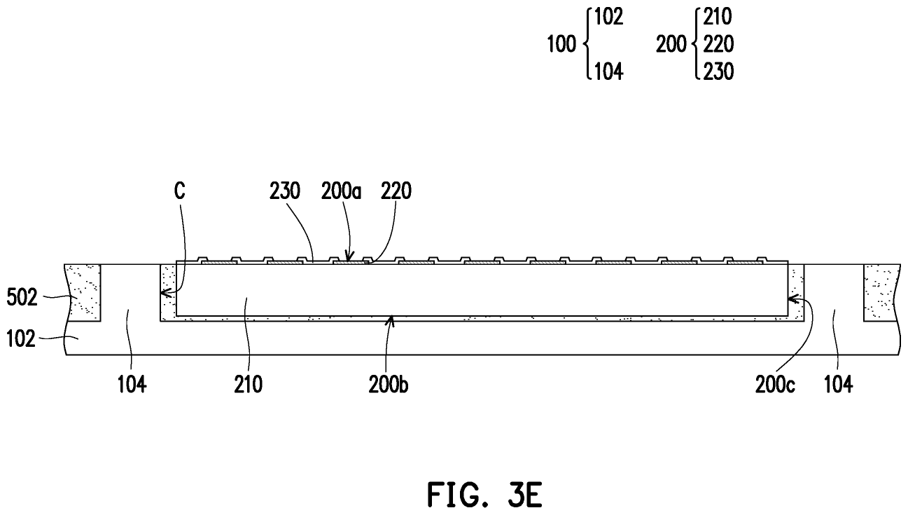

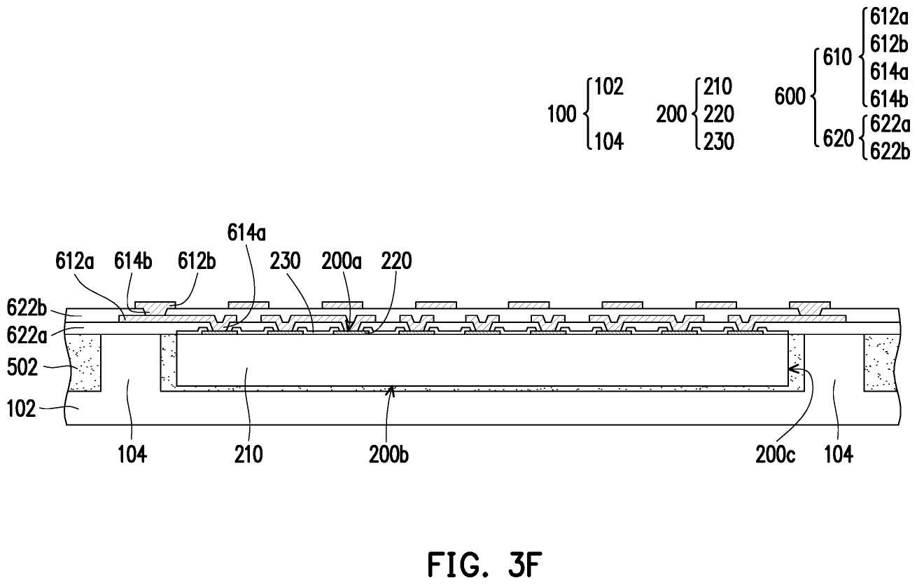

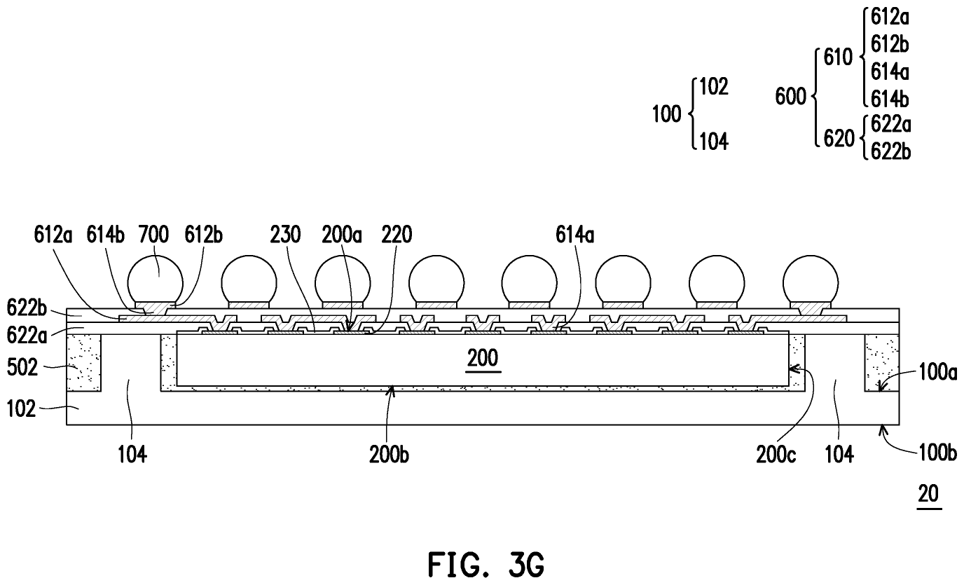

FIG. 3A to FIG. 3G are schematic cross-sectional views illustrating a manufacturing method of a package structure 20 according to some alternative embodiments of the disclosure. Referring to FIG. 3A, a carrier 800 is provided and an adhesive layer 900 is formed on the carrier 800. The carrier 800 may be a glass substrate or a glass supporting board. However, they construe no limitation in the disclosure. Other suitable substrate materials may be adapted as the carrier 800 as long the material is able to withstand the subsequent processes while carrying the package structure formed thereon. The adhesive layer 900 may be formed on the carrier 800 to temporarily enhance the adhesion between the carrier 800 and other structures subsequently formed thereon. The adhesive layer 900 may be a light to heat conversion (LTHC) adhesive layer. However, the disclosure is not limited thereto, and other suitable adhesive layers may be used in some alternative embodiments. For example, the adhesive layer 900 may include epoxy resins, inorganic materials, organic polymeric materials, or other suitable adhesive materials.

Referring to FIG. 3B, a die 200 and a frame structure 100 are sequentially placed on the adhesive layer 900. The die 200 and the frame structure 100 may be similar to that used in the embodiment of FIG. 1A and FIG. 1B, thus will not be described for brevity. As illustrated in FIG. 3B, the die 200 is placed such that the active surface 200a of the die 200 faces the carrier 800 while the rear surface 200b of the die 200 faces up. In some embodiments, the rear surface 200b of the die 200 is pressed such that the connection pads 220 are completely embedded in the adhesive layer 900. After fixing the die 200 onto the adhesive layer 900, the frame structure 100 is disposed on the adhesive layer 900 such that the die 200 is covered by the cavity C of the frame structure 100. In other words, the protrusion 104 of the frame structure 100 faces the carrier 800 to surround the die 200. In some embodiments, a surface 104a of the frame structure 100 is in physical contact with the adhesive layer 900. On the other hand, the frame structure 100 may be spaced apart from the die 200. For example, the rear surface 200b and lateral sides 200c of the die 200 may not be in contact with the frame structure 100. In some embodiments, since the protrusion 104 of the frame structure 100 surrounds the die 200, the frame structure 100 may be electrically grounded to provide the function of EMI shielding.

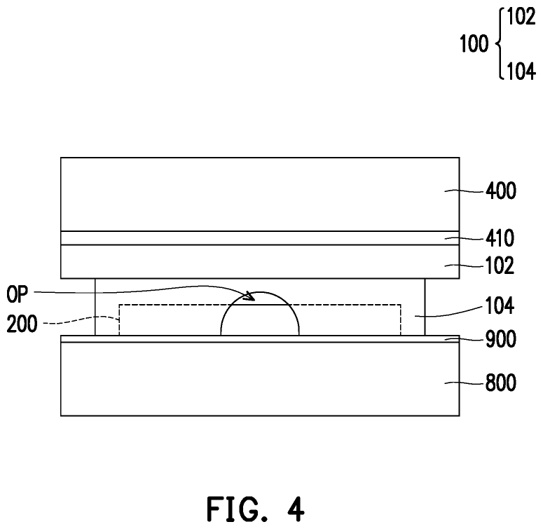

Referring to FIG. 3C, a mold chase 400 having a sealing film 410 formed thereon is placed over the second surface 100b of the frame structure 100. The mold chase 400 and the sealing film 410 may be similar to that used in the embodiment of FIG. 1C, thus will not be described for brevity. As illustrated in FIG. 3C, the sealing film 410 is disposed between the mold chase 400 and the second surface 100b of the frame structure 100. In other words, the frame structure 100 is in physical contact with the sealing film 410. In some embodiments, the frame structure 100 has at least one through opening. FIG. 4 is a schematic side view illustrating an intermediate stage of the manufacturing method shown in FIG. 3C. The protrusion 104 of the frame structure 100 has at least one through opening OP. The through opening OP exposes at least a portion of the die 200 from the side view. For example, the lateral sides 200c of the die 200 may be seen through the through opening OP from the side. The through opening OP may be a semicircular opening formed on a sidewall of the protrusion 104, thereby forming an arch structure. However, the disclosure is not limited thereto. In some alternative embodiments, the through opening OP may be a rectangular opening, a circular opening, or an opening with other geometries. The protrusion 104 may only encompass one through opening OP. Nevertheless, the disclosure is not limited thereto. In some alternative embodiments, the protrusion 104 may include multiple through openings OP. The through openings OP may be located on a single sidewall of the protrusion 104 or may be found on multiple sidewalls of the protrusion 104.

Referring to FIG. 3D, an encapsulation material 500 is filled into a gap between the die 200 and the frame structure 100 and a gap between the frame structure 100 and the adhesive layer 900. The encapsulation material 500 may be similar to that used in the embodiment of FIG. 1D, thus will not be described for brevity. The encapsulation material 500 may be in solid form at room temperature. In some embodiments, the encapsulation material 500 is first melted. Subsequently, the encapsulation material 500 is transferred or forced into the gap between the die 200 and the frame structure 100 and the gap between the frame structure 100 and the adhesive layer 900. The encapsulation material 500 is able to flow into the cavity C of the frame structure 100 through the through opening OP to fill the gap between the die 200 and the frame structure 100. The through opening OP may also be filled by the encapsulation material 500. In some embodiments, the encapsulation material 500 is forced into the gaps along a direction parallel to the rear surface 200b of the die 200. The encapsulation material 500 may be transferred into the gaps from a horizontal direction. In some embodiments, the foregoing process may be referred to as a transfer molding process. During the transfer molding process, a clamp force may be applied onto the mold chase 400 such that sealing film 410 is firmly pressed against the second surface 100b of the frame structure 100. Since the connection pads 220 of the die 200 are well protected and sealed by the adhesive layer 900, the adhesive layer 900 may block the encapsulation material 500 from damaging the connection pads 220 during the transfer molding process. That is, during the transfer molding process, the adhesive layer 900 is able to protect the active surface 200a of the die 200 from molding penetration. As such, the electrical connection between the connection pads 220 and the subsequently formed elements may be ensured, thereby enhancing the reliability of the subsequently formed package structure 20.

Referring to FIG. 3E, the mold chase 400 and the sealing film 410 are removed and the encapsulation material 500 is cured to form an encapsulant 502. In some embodiments, the curing temperature may range between 130° C. and 175° C. The encapsulant 502 is formed over the frame structure 100 and fills into the cavity C of the frame structure 100. For example, the encapsulant 502 encapsulates the rear surface 200b and lateral sides 200c of the die 200. Since the encapsulant 502 is formed to fill the gap between the die 200 and the frame structure 100 and the gap between the frame structure 100 and the adhesive layer 900 (shown in FIG. 3D), at least a portion of the encapsulant 502 is disposed between the die 200 and the frame structure 100. For example, a portion of the encapsulant 502 is disposed between the lateral sides 200c of the die 200 and the protrusion 104 of the frame structure 100. Meanwhile, a portion of the encapsulant 502 is disposed between the rear surface 200b of the die 200 and the body 102 of the frame structure 100. Moreover, a portion of the encapsulant 502 is also filled into the through opening OP of the protrusion 104 of the frame structure 100.

After forming the encapsulant 502, the adhesive layer 900 and the carrier 800 may be separated from the encapsulant 502, the frame structure 100, and the active surface 200a of the die 200. As mentioned above, the adhesive layer 900 may be an LTHC layer. Upon exposure to a UV laser, the adhesive layer 900 and the carrier 800 may be peeled off and separated from the die 200, the encapsulant 502, and the frame structure 100. Upon removal of the carrier 800 and the adhesive layer 900, the active surface 200a of the die 200 is exposed.

The steps illustrated in FIG. 3F to FIG. 3G may be similar to the steps described in FIG. 1F to FIG. 1G, so the detailed descriptions thereof are omitted herein. As illustrated in FIG. 3G, the package structure 20 is obtained. In the package structure 20, the frame structure 100 is in physical contact with the redistribution layer 600. For example, the protrusion 104 of the frame structure 100 is in physical contact with the first dielectric layer 622a to provide a more rigid and stronger structural support for the package structure 20. Moreover, since the protrusion 104 surrounds the die 200, the frame structure 100 is able to provide the function of EMI shielding, thereby improving the electrical performances of the package structure 20. The frame structure 100 of the package structure 20 may serve as a carrier during a portion of the manufacturing process of the package structure 20. Thus, the use of a temporary carrier may be eliminated. In other words, the costly transfer bonding process performed in the conventional manufacturing process of the package structure may be removed to reduce the cost of fabrication. Moreover, since the frame structure 100 may be formed by rigid materials, the frame structure 100 is able to provide rigidity and strength to the package structure. As such, the problems of panel warpage and package chipping/breaking/cracking may be sufficiently prevented, thereby increasing the yield and the reliability of the package structure 20. Furthermore, since the frame structure 100 may be made of a material having low thermal capacity and high thermal dissipation, the frame structure 100 may also serve the function of heat dissipation. As a result, the performance of the package structure 20 may be further enhanced.

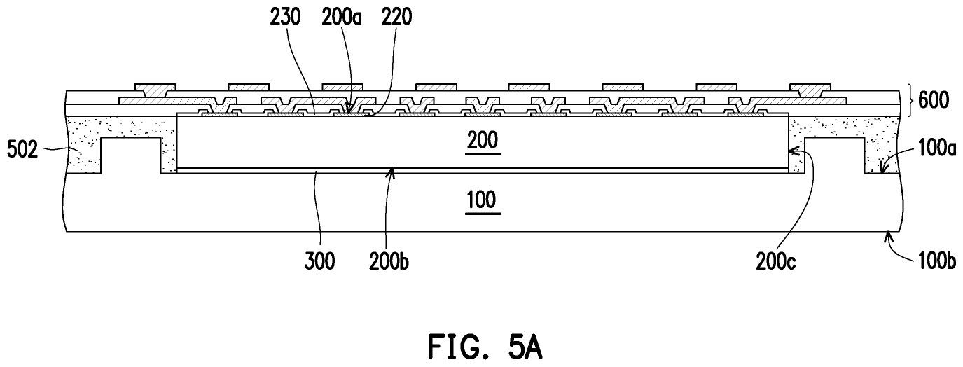

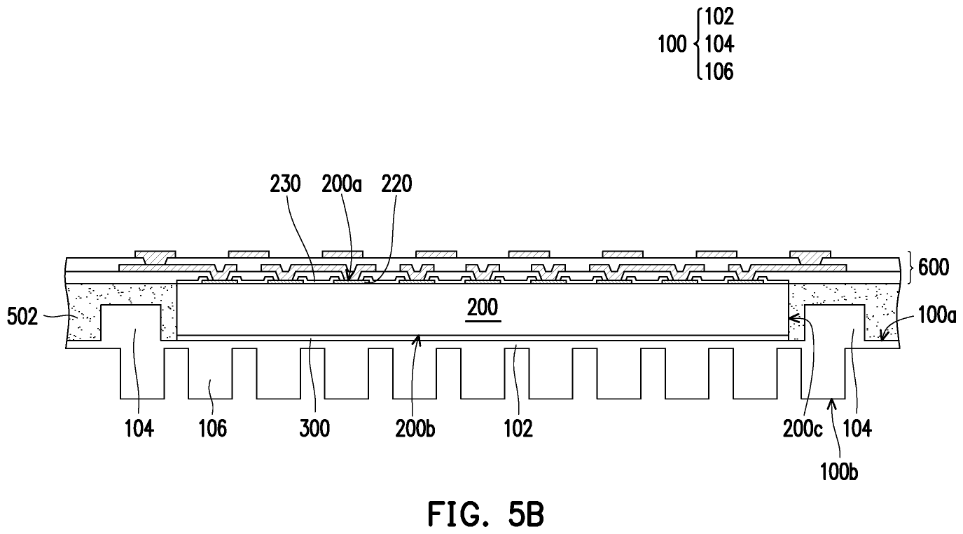

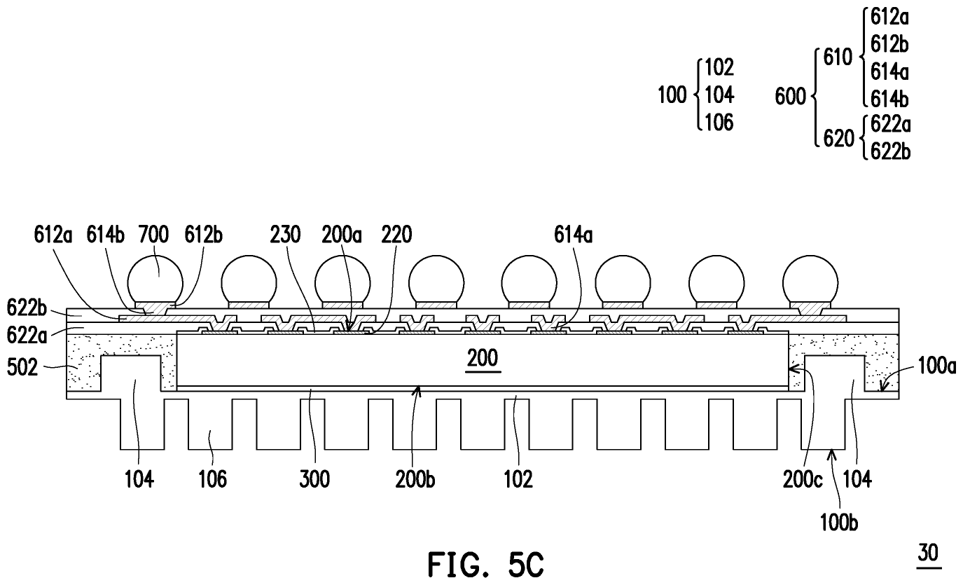

FIG. 5A to FIG. 5C are cross-sectional views illustrating some steps of a manufacturing method of a package structure 30 according to some embodiments of the disclosure. The structure illustrated in FIG. 5A may be obtained by performing the steps similar to the steps described in FIG. 1A to FIG. 1F, so the detailed descriptions thereof are omitted herein.

Referring to FIG. 5B, the second surface 100b of the frame structure 100 is patterned to form a plurality of fins 106. A photolithography process and an etching process may be performed on the second surface 100b (the surface of the frame structure 100 opposite to the cavity C) of the frame structure 100 to form the fins 106. The etching process includes a wet etching process or a dry etching process. In some embodiments, the frame structure 100 is constituted by the body 102, the protrusion 104, and the fins 106. As illustrated in FIG. 5B, the protrusion 104 and the fins 106 are located on two opposite sides of the body 102. The number of the fins 106 may be greater than the number of the protrusion 104. In some embodiments, the fins 106 may serve as a heat sink for thermal dissipation. For example, the fins 106 are able to provide a larger contact area/interface between the frame structure 100 and the surrounding (for example, the ambient air). Due to the larger contact area between the frame structure 100 and the surrounding, the heat may be dissipated to the surrounding at a faster rate. As illustrated in FIG. 5B, the fins 106 are shown as rectangular protrusions, but the disclosure is not limited thereto. In some alternative embodiment, the fins 106 may be triangular protrusions, semicircular protrusions, or protrusions with other types of lines and shapes. Although the foregoing patterning process is performed on the structure illustrate in FIG. 5A, the disclosure is not limited thereto. In some alternative embodiments, the foregoing patterning process may be performed on the structure illustrated in FIG. 3F as well to form the fins.

Referring to FIG. 5C, a plurality of conductive terminals 700 are formed over the redistribution structure 600 and a singulation process is performed to obtain the package structure 30. The steps illustrated in FIG. 5C may be similar to the step described in FIG. 1G, so the detailed descriptions thereof are omitted herein.

As mentioned above, since the frame structure 100 may be made of a material having low thermal capacity and high thermal dissipation, the frame structure 100 may serve the function of heat dissipation. Moreover, the adaption of the fins 106 in the frame structure 100 allows the heat to dissipate at a faster rate. As a result, the performance of the package structure 30 may be further enhanced.

Based on the above, the frame structure within the package structure may serve as a carrier during the manufacturing process of the package structure. Thus, the use of a temporary carrier may be eliminated. In other words, the costly transfer bonding process performed in the conventional manufacturing process of the package structure may be removed to reduce the cost of fabrication. Moreover, since the frame structure may be formed by rigid materials, the frame structure is able to provide rigidity and strength to the package structure. As such, the problems of panel warpage and package chipping/breaking/cracking may be sufficiently prevented, thereby increasing the yield and the reliability of the package structure. Furthermore, the frame structure may also serve the function of heat dissipation and EMI shielding. As a result, the performance of the package structure may be further enhanced.

It will be apparent to those skilled in the art that various modifications and variations can be made to the embodiments and concepts disclosed herein without departing from the scope or spirit of the invention. In view of the foregoing, it is intended that the present disclosure cover modifications and variations of this invention provided they fall within the scope of the following claims and their equivalents.

1. A package structure, comprising:
a one-piece metal frame structure having a cavity, wherein the one-piece metal frame structure comprises a body and a protrusion protruding from the body, and the body and the protrusion are configured to form the cavity;
a die disposed in the cavity, the die having an active surface, a rear surface opposite to the active surface, a plurality of lateral sides connecting the active surface and the rear surface, and a plurality of connection pads disposed on the active surface, wherein the protrusion of the one-piece metal frame structure forms a closed loop surrounding the die;
an encapsulant encapsulating at least a portion of the one-piece metal frame structure and the plurality of lateral sides of the die; and
a redistribution structure disposed on the encapsulant and the active surface of the die, wherein the plurality of connection pads is in physical contact with the redistribution structure.

2. (canceled)

3. The package structure according to claim 1, wherein a portion of the encapsulant is formed between the protrusion and the redistribution structure.

4. The package structure according to claim 1, wherein the protrusion is in physical contact with the redistribution structure, and the protrusion comprises at least one through opening having the encapsulant filled therein.

5. The package structure according to claim 1, wherein the one-piece metal frame structure further comprises a plurality of fins opposite to the protrusion.

6. The package structure according to claim 1, wherein at least a portion of the encapsulant is disposed between the plurality of lateral sides of the die and the protrusion of the one-piece metal frame structure.

7. The package structure according to claim 1, wherein at least a portion of the encapsulant is disposed between the rear surface of the die and the body of the one-piece metal frame structure.

8. The package structure according to claim 1, further comprising an adhesive layer disposed between the rear surface of the die and the body of the one-piece metal frame structure.

9. The package structure according to claim 1, wherein a material of the one-piece metal frame structure comprises copper, metallic alloy, steel, or a combination thereof.

10. The package structure according to claim 1, further comprising a plurality of conductive terminals disposed on the redistribution structure opposite to the die.

11. A manufacturing method of a package structure, comprising:
providing a one-piece metal frame structure having a cavity, wherein the one-piece metal frame structure comprises a body and a protrusion protruding from the body, and the body and the protrusion are configured to form the cavity;
placing a die in the cavity of the one-piece metal frame structure, wherein the die has an active surface, a rear surface opposite to the active surface, a plurality of lateral sides connecting the active surface and the rear surface, and a plurality of connection pads disposed on the active surface, and the protrusion of the one-piece metal frame structure forms a closed loop surrounding the die;
placing a mold chase having a sealing film formed thereon over the one-piece metal frame structure and the die;
forming an encapsulant to encapsulate at least a portion of the one-piece metal frame structure and the plurality of lateral sides of the die; and
forming a redistribution structure over the encapsulant and the die, wherein the plurality of connection pads is in physical contact with the redistribution structure.

12. The method according to claim 11, wherein the step of placing the die in the cavity of the one-piece metal frame structure comprises:
forming an adhesive layer on the rear surface of the die; and
placing the die in the cavity of the one-piece metal frame structure such that the rear surface of the die is attached to the one-piece metal frame structure through the adhesive layer.

13. The method according to claim 12, wherein the step of placing the mold chase having the sealing film formed thereon over the one-piece metal frame structure and the die comprises:
placing the mold chase having the sealing film formed thereon onto the active surface of the die such that the plurality of connection pads of the die is embedded in the sealing film, wherein the one-piece metal frame structure is separated from the sealing film.

14. The method according to claim 12, wherein the step of forming the encapsulant comprises:
filling an encapsulation material into a gap between the sealing film, the one-piece metal frame structure, and the die; and
curing the encapsulation material to form the encapsulant.

15. The method according to claim 11, wherein the step of placing the die in the cavity of the one-piece metal frame structure comprises:
providing a carrier;
forming an adhesive layer on the carrier;
placing the die on the adhesive layer such that the active surface of the die faces the carrier, wherein the plurality of connection pads is embedded in the adhesive layer; and
placing the one-piece metal frame structure on the adhesive layer such that the die is disposed in the cavity of the one-piece metal frame structure.

16. The method according to claim 15, wherein the step of placing the mold chase having the sealing film formed thereon over the one-piece metal frame structure and the die comprises:
placing the mold chase having the sealing film formed thereon onto the one-piece metal frame structure, wherein the one-piece metal frame structure is in physical contact with the sealing film.

17. The method according to claim 15, wherein the step of forming the encapsulant comprises:
filling an encapsulation material into a gap between the die and the one-piece metal frame structure and a gap between the one-piece metal frame structure and the adhesive layer; and
curing the encapsulation material to form the encapsulant.

18. The method according to claim 15, further comprising removing the adhesive layer and the carrier from the one-piece metal frame structure and the active surface of the die after the encapsulant is formed.

19. The method according to claim 11, further comprising patterning a surface of the one-piece metal frame structure opposite to the cavity to form a plurality of fins.

20. The method according to claim 11, further comprising forming a plurality of conductive terminals on the redistribution structure opposite to the die.
